(19) United States
(12) Patent Application Publication
(10) Pub. No.: US 2006/0240669 A1
(43) Pub. Date: Oct. 26, 2006

(54) Method of forming vapor-deposited film and method of manufacturing EL display device

(75) Inventors: Katsuhiro Kaneko, Yasu-shi (JP); Yoshiro Takeda, Yasu-shi (JP); Kazumasa Kobayashi, Yasu-shi (JP); Eiho Chin, Yasu-shi (JP); Koji Murayama, Yasu-shi (JP)

Correspondence Address: VOLPE AND KOENIG, P.C., UNITED PLAZA, SUITE 1600, 30 SOUTH 17TH STREET, PHILADELPHIA, PA, 19103, US

(73) Assignee: KYOCERA Corporation, Fushimi-ku (JP)

(21) Appl. No.: 11/412,019

(22) Filed: Apr. 26, 2006

(30) Foreign Application Priority Data
Apr. 26, 2005 (JP) 2005-127395
Feb. 22, 2006 (JP) 2006-45233

(51) Int. Cl. H01L 21/44

(52) U.S. Cl. 438/680

(57) ABSTRACT

A method of forming a vapor-deposited film includes the steps of: aligning a mask having a plurality of openings with a substrate; forming a film on the substrate through the openings of the mask by the use of a vapor deposition method; and cleaning the mask in a state that the top surface and the bottom surface of the mask used for forming the film are not inverted to maintain the vertical relation of the mask.

### CROSS-REFERENCE TO RELATED APPLICATIONS

The present application claims priority to Japanese Patent Applications No. 2005-127395, filed Apr. 26, 2005, and No. 2006-45233, filed Feb. 22, 2006. The contents of that application are incorporated herein by reference in their entirety.

### BACKGROUND OF THE INVENTION

1. Field of the Invention

The present invention relates to a method of forming a vapor-deposited film using a mask and a method of manufacturing an EL display device.

2. Description of the Related Art

As a method of forming an electrode layer, a light emitting layer, and the like in a method of manufacturing an EL display device such as an organic EL display device, there is generally known a vacuum deposition method using a vapor-deposition mask.

Hereinafter, for the purpose of convenient description, an EL display substrate is simply referred to as a substrate and it is supposed that a substrate denoted an organic EL display substrate. Also, in the following description, the positioning between the substrate and the vapor-deposition mask is simply referred to as positioning or alignment.

A method of forming organic EL elements of red (R), green (G), and blue (B) on a main surface (which is the bottom surface) of a display substrate by the use of the vacuum deposition method approximately includes the following process steps (1) to (7). Here, the organic EL elements have a structure that a positive electrode, a hole injecting layer, a hole transporting layer, a light emitting layer, an electron transporting layer, and a negative electrode are sequentially stacked.

(1) An entire-surface deposition mask is disposed on the bottom surface of a substrate on which a positive electrode is formed and an evaporation source on which a material is piled is disposed below the entire-surface deposition mask. An organic material on the evaporation source is vaporized and the vaporized material is deposited on the substrate through the entire-surface deposition mask, thereby forming a hole injecting layer on the positive electrode (see FIG. 9A).

(2) Next, the material on the evaporation source is replaced and then a hole transporting layer is deposited on the hole injecting layer by the use of the entire-surface deposition mask similarly to the process step (1) (see FIG. 9B).

(3) Next, the material on the evaporation source is replaced and the entire-surface deposition mask is replaced with a sub-pixel deposition mask having a plurality of openings corresponding to the respective color sub pixels.

(4) The sub-pixel deposition mask is aligned with the substrate and then a red light emitting layer is deposited on the hole transporting layer by the use of the sub-pixel deposition mask (see FIG. 9C).

(5) Next, the material on the evaporation source is replaced, the sub-pixel deposition mask is moved horizontally, and then a green light emitting layer is deposited on the hole transporting layer by the use of the sub-pixel deposition mask (see FIG. 9D).

(6) Also, the material on the evaporation source is replaced, the sub-pixel deposition mask is moved horizontally, and then a blue light emitting layer is deposited on the hole transporting layer by the use of the sub-pixel deposition mask (see FIG. 9E).

(7) Next, the sub-pixel deposition mask is replaced with the entire-surface deposition mask and the material on the evaporation source is replaced.

(8) Subsequently, an electron transporting layer is deposited on the respective light emitting layers by the use of the entire-surface deposition mask (see FIG. 9F).

(9) And, the material on the evaporation source is replaced and then a negative electrode layer is similarly deposited on the electron transporting layer by the use of the entire-surface deposition mask to form organic EL elements of R, G, and B (see FIG. 9G).

In the mask used in the vapor deposition method, the deposition materials are attached to the bottom surface (the opposite surface of the surface opposed to the substrate) or the inner surfaces of the openings thereof. When another material is deposited by the use of the mask in which large amount of the material is attached to the bottom surface of the mask or the inner surfaces of the openings, the material attached to the mask is mixed as impurities, thereby making it difficult to form a desired vapor-deposited film.

Accordingly, in order to remove the material attached to the mask, it is necessary to clean the mask. An example of such a cleaning method is disclosed in JP 2003-332052. The cleaning method disclosed in JP 2003-332052 is as follows.

(1) First, organic layers corresponding to red, green, and blue are formed on a substrate by the use of a vapor deposition mask in a vacuum chamber 21.

(2) Next, the used mask is transferred to a cleaning chamber.

(3) Subsequently, the used mask is cleaned in the cleaning chamber. Specifically, as shown in FIG. 10, after the mask 24 is mounted on a lower electrode 25, discharging gas is supplied to the interior of a room from a gas supply source, and a high-frequency current is supplied to the electrodes from a high-frequency power source, thereby generating plasma gas between an upper electrode 26 and the lower electrode 25 by high-frequency discharge. Then, the material attached to the mask is removed by the use of the generated plasma gas.

In the cleaning method disclosed in JP 2003-332052, since the gas used for the cleaning is the high-energy plasma gas generated by the high-frequency plasma discharge and the plasma gas is generated at the same place as the place where the plasma gas comes in contact with the surface of the mask, physical impact acting on the surface of the mask is very strong and thus the mask 24 is greatly etched, thereby damaging the mask. Further, there is a problem that deformation or variation in size is caused in the mask due to the heat generated through the physical impact. In addition, a cleaning target on the mask surface, that is, the organic EL material, can be reformed by the plasma gas, thereby making it difficult to remove the cleaning target. Accordingly, residue can remain and thus the cleaning target cannot be satisfactorily removed.

Since vapor deposition generally fly vaporized particles from bottom to top, the organic EL material as the cleaning target is mostly attached to the bottom surface of the mask 24. Accordingly, when it is intended to clean the bottom surface of the mask by the use of the cleaning apparatus disclosed in JP 2003-332052, the mask must be mounted on the electrode with the top and the bottom surfaces inverted. Therefore, a large-scaled mechanism for inverting the mask 24 and a sufficient space for installing the inverting mechanism are required. As a result, the increase in complexity and size of the cleaning apparatus is caused and the tact time for the inversion is also required, thereby deteriorating production efficiency.

The materials may be attached to the top surface of the mask through the openings of the mask, in addition to the bottom surface of the mask 24. However, since the mask 24 is mounted on the lower electrode 25 for cleaning in the cleaning method disclosed in JP 2003-332052, there is a problem that only one surface of the mask 24 can be cleaned.

### SUMMARY OF THE INVENTION

According to an aspect of the present invention, there is provided a method of forming a vapor-deposited film includes the steps of: aligning a mask having a plurality of openings with a substrate; forming a film on the substrate through the openings of the mask by the use of a vapor deposition method; and cleaning the mask in a state that the top surface and the bottom surface of the mask used for forming the film are not inverted to maintain the vertical relation of the mask.

According to another aspect of the invention, there is provided a method of manufacturing an EL display device comprising the steps of: aligning a mask having a plurality of openings with a first display substrate; depositing a first organic material on the first display substrate through the openings of the mask and forming a first organic light emitting layer on the first display substrate; cleaning the mask in a state that the top surface and the bottom surface of the mask used for forming the first organic light emitting layer are not inverted to maintain the vertical relation of the mask; aligning the cleaned mask with a second display substrate; and depositing a second organic material on the second display substrate through the openings of the mask and forming a second organic light emitting layer on the second display substrate.

### BRIEF DESCRIPTION OF THE DRAWINGS

FIG. 1 is a cross-sectional view illustrating a cleaning apparatus according to an embodiment of the present invention;

FIG. 2 is a cross-sectional view illustrating a state that a metal mask and a magnet plate are supported by a support member shown in FIG. 1;

FIG. 3 is a cross-sectional view illustrating a state that a metal mask, an intermediate plate, and a magnet plate are supported by a support member of a cleaning apparatus according to the present invention;

FIG. 4A is a plan view of the magnet plate shown in FIG. 3, FIG. 4B is a plan view of the intermediate plate shown in FIG. 3, and FIG. 4C is a plan view of the metal mask shown in FIG. 3;

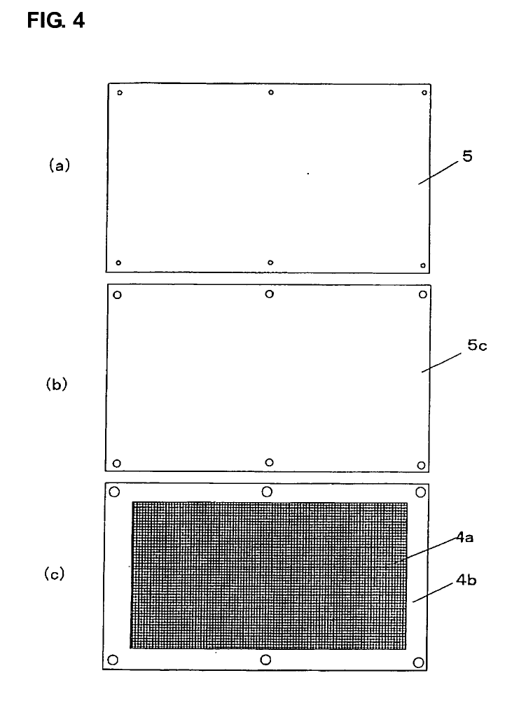

FIG. 5 is a schematic plan view illustrating a configuration of an apparatus for manufacturing an organic EL display device according to the present invention;

FIG. 6 is a cross-sectional view of an alignment unit constituting a method of manufacturing the organic EL display device shown in FIG. 5;

FIG. 7 is a cross-sectional view of a film forming apparatus constituting the apparatus for manufacturing the organic EL display device shown in FIG. 5;

FIG. 8 is a cross-sectional view illustrating a cleaning apparatus according to another embodiment of the present invention;

FIGS. 9A to 9G are plan views illustrating a conventional method of manufacturing an organic EL display device; and

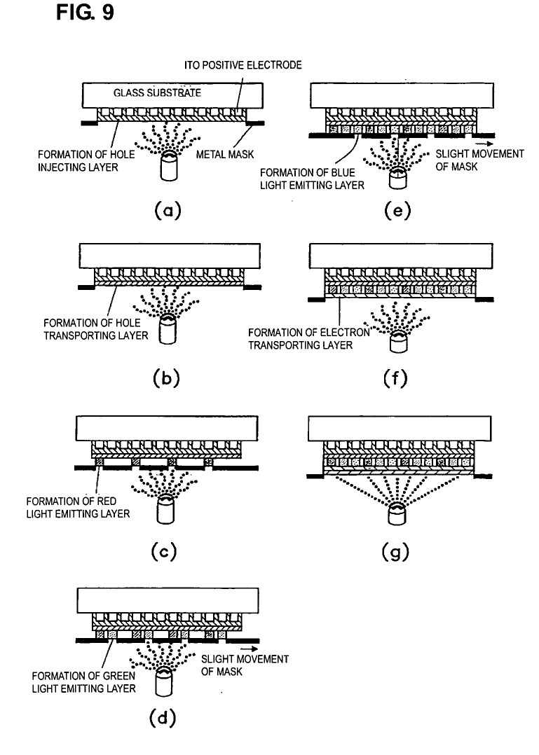

FIG. 10 is a cross-sectional view illustrating a configuration of a conventional cleaning apparatus.

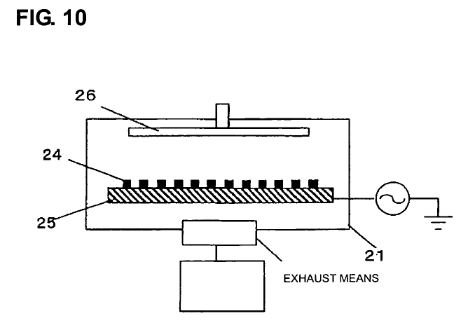

### DESCRIPTION OF THE EXEMPLARY EMBODIMENTS

A cleaning apparatus and an apparatus of manufacturing an EL display device according to an embodiment of the present invention will be described with reference to the drawings.

Mask Cleaning Apparatus

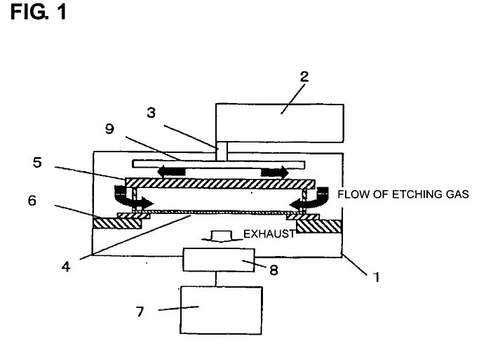

FIG. 1 is a cross-sectional view illustrating a cleaning apparatus according to an embodiment of the invention. The mask cleaning apparatus according to the embodiment includes a vacuum chamber 1, a high-frequency plasma source 2 for generating etching gas for etching organic materials attached to a metal mask 4, a guide port 3 (guide mechanism) for guiding the etching gas into the vacuum chamber 1, a support member 6 for supporting the metal mask 4 and a magnet plate 5 with a predetermined distance therebetween, an exhaust port 8 (exhaust mechanism) connected to a vacuum pump 7 and disposed below the metal mask 4, and a carrying means (not shown) for carrying the metal mask 4 and the magnet plate 5 to and from the vacuum chamber 1. The mask cleaning apparatus serves to remove the organic materials attached to the metal mask 4 and the magnet plate 5 by the use of the etching gas introduced into the vacuum chamber 1.

The mask cleaning apparatus may include a shower head 9 (guide mechanism) having a plurality of holes for jetting the etching gas in a predetermined direction within the vacuum chamber 1. The shower head 9 is connected to the guide port 3.

The vacuum chamber 1 is made of a well-known vacuum chamber material such as aluminum or SUS, for example. Since the surface of the vacuum chamber 1 is coated with polytetrafluoroethylene, the loss of activity of the etching gas in the vacuum chamber 1 is suppressed, thereby enhancing the mask cleaning effect.

The high-frequency plasma source 2 may be a high-frequency oscillator as an example and serves to excite the etching gas to plasma with high frequency of 13.56 MHz or 2.45 GHz bandwidth industrially used. Specifically, when microwaves of 2.45 GHz are used as the high frequency, it is possible to generate etching gas containing radicals which can efficiently etch the organic EL material attached to the mask with high density.

The high-frequency plasma source 2 is disposed in an area other than the area in which the metal mask 4 and the magnet plate 5 are disposed. In the present embodiment, the high-frequency plasma source 2 is received in a chamber other than the vacuum chamber 1.

As the etching gas generated by the high-frequency plasma source 2, CF-grouped gas such as CF₄, C₂F₆, and C₃F₈, or mixture gas of the CF-grouped gas, O₂, and rare gas such as N₂, Ar, and Xe is used. The etching gas generated by the high-frequency plasma source 2 is in the plasma state.

The etching gas generated by the high-frequency plasma source 2 is introduced in a predetermined direction corresponding to a pressure gradient of vacuum exhaust by the exhaust port 8. The introduced etching gas is guided to an area in which the metal mask 4 and the magnet plate 5 are installed in the vacuum chamber 1, through a guide means such as a guide port 3 and a shower head 9.

The etching gas guided to the vacuum chamber 1 through the guide port 3 and the shower head 9 contains radicals, ions, and the like since the etching gas is excited by plasma. The ions in the etching gas are electrically attracted to and are often contacted with the wall surface of the guide port 3 or the shower head 9 in the course of guidance of the etching gas to the vacuum chamber 1. As a result, the ions in the etching gas can lose activity to change into neutral radicals. On the other hand, the radicals in the etching gas tend to lose activity thereof through the coupling to other atoms, but maintain the radical status so long as they do not collide with reaction counterparts. That is, the radicals have a lifetime longer than that of the ions. Accordingly, the etching gas in the course of guidance of the etching gas to the vacuum chamber 1 mainly includes the radicals.

Since the radicals are neutral particles having lower energy than that of plasma, the damage on the mask due to the etching gas can be reduced by cleaning the mask by the use of the etching gas mainly including the radicals. That is, charged particles in plasma are accelerated by self bias generated in the vicinity of the surface of the mask to apply physical impact to the mask, while the radicals which are electrically neutral are little accelerated by the self bias and thus the physical impact on the mask is very small.

The reason for removing the materials attached to the mask by the use of the etching gas is that when the radicals such as fluorine radicals and oxygen radicals in the etching gas come in contact with the materials attached to the mask, the attached materials (organic EL materials) are changed to other materials which can be vaporized such as water, carbon dioxide, and metal fluoride, through chemical reaction.

Since the organic material used for the organic layer of the organic EL display device contains C, H, and N as the main components and also contains metal complex, the organic material can be efficiently removed by using fluorine radicals as well as oxygen radicals as the etching gas. When rare gas such as N₂, Ar, and Xe is added to the etching gas, the oxygen radicals and the fluorine radicals can serve as carrier gas for carrying the etching gas and the etching product and thus the gas can be excellently exhausted, thereby performing a cleaning process without residues. The kind and flow rate of the etching gas can be determined through experiments in consideration of a desired etching characteristic, that is, a desired cleaning ability. When the flow rate ratio of the CF-grouped gas to the O₂ gas is greater than 0.5, the CF-grouped polymers can be easily deposited. On the other hand, when the flow rate ratio of the CF-grouped gas to the O₂ gas is smaller than 0.05, the etching rate is decreased. Therefore, the (flow rate of CF-grouped gas)/(flow rate of O₂ gas) is preferably set in the range of 0.05 to 0.5. The flow rate of the CF-grouped gas is preferably in the range of 10 sccm to 500 sccm. When rare gas is introduced into the etching gas, the (flow rate of rare gas)/(flow rate of O₂ gas) is preferably set in the range of 5% to 20%.

The metal mask 4 is a structure obtained by fixing a metal mask sheet 4a made of a magnetic material such as nickel or nickel alloy to a mask frame 4b made of aluminum or SUS, and the like by means of tension. An example of the nickel-based alloy is nickel-cobalt alloy. The metal mask 4 is manufactured by an electroforming method or an etching method. The thickness of the metal mask sheet 4a is in the approximate range of 10 μm to 30 μm. A plurality of openings is formed through the metal mask sheet 4a for transmitting vaporized particles. Accordingly, the constituent material for a light emitting layer or an electrode layer is deposited on the substrate through the openings, thereby forming the light emitting layer or the electrode layer on the substrate.

The magnet plate 5 is a plate made of SUS or aluminum, etc., and a magnet 5b is disposed in the inside or the surface of the plate and is disposed on metal mask 4. At the time of deposition to the substrate, the magnet plate 5 is disposed on the metal mask 4. The magnet plate 5 serves to attract the metal mask 4 to the side of the magnet plate 5 by means of the magnetic force of the magnet plate 5 and to fix the metal mask 4 with respect to the substrate interposed between the metal mask 4 and the magnet plate 5.

The metal mask 4 and the magnet plate 5 have a hole for inserting a support member 6 to be described later at the ends thereof, respectively. Since the metal mask 4 and the magnet plate 5 are disposed with a predetermined gap therebetween by the support member 6, most of the top surface and the bottom surface of the metal mask 4 and the magnet plate 5 are exposed and thus the metal plate 4 and the magnet plate 5 are well cleaned by the etching gas.

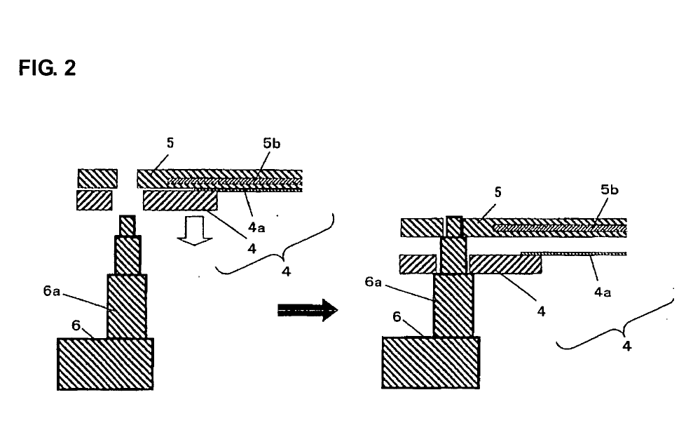

As shown in FIG. 2, the support member 6 has a structure that a plurality of protrusions 6a, 6b, and 6c is stacked in the thickness direction of the metal mask 4. The widths of the protrusions become smaller toward the front end of the support member 6. The hole diameter of the magnet plate 5 is smaller than those of the protrusions 6a and 6b and greater than that of the protrusion 6c. On the other hand, the hole diameter of the metal mask 4 is smaller than that of the protrusion 6a and greater than those of the protrusions 6b and 6c. Therefore, when the support member 6 is inserted into the hole of the metal mask 4 and the magnet plate 5, the metal mask 4 is vertically supported by the protrusion 6a and the magnet plate 5 is vertically supported by the protrusion 6b, respectively.

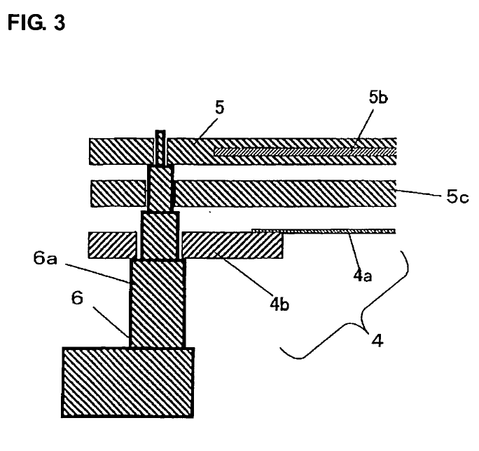

The support member 6 is inserted into the holes of the metal mask 4 and the magnet plate 5 by disposing the metal mask 4 and the magnet plate 5 fixed to each other with a magnetic force above the support member 6, lowering the metal mask 4 and the magnet plate 5, and inserting the protrusions of the support member into the holes of the metal mask 4 and the magnet plate 5. After the insertion, the magnet plate 5 and the metal mask 4 are separated from each other by application of an external force. At this time, when the magnetic force of the magnet plate 5 is too large, the external force necessary for the separation is increased, thereby deforming or damaging the metal mask 4. Accordingly, an intermediate plate 5c made of SUS or aluminum, and the like having a magnetic force smaller than that of the magnet plate 5 may be interposed between the metal mask 4 and the magnet plate 5(see FIG. 3). When the intermediate plate 5c is used, the deformation or the damage of the metal mask 4 can be suppressed by first separating the magnet plate 5 and the intermediate plate 5c from each other and then separating the intermediate plate 5c and the metal mask 4 from each other.

It is preferable that the gap between the metal mask 4 and the magnet plate 5 is 5 mm or more (more preferably, 10 mm or more). More preferably, the gap is ten or more times as large as a mean free path of the etching gas. The etching gas can be diffused sufficiently wide by setting the gap to the above-mentioned value. On the other hand, it is preferable that the gap is 50 mm or less. When the gap is greater than 50 mm, the chamber volume is uselessly increased without improving the etching effect.

Since the surfaces of the magnet plate 5 and the intermediate plate 5c are coated with polytetrafluoroethylene, the deactivation of the active etching gas can be suppressed, thereby etching and removing the organic materials at a higher rate.

As the vacuum pump 7, a pump having sufficient resistance to the etching gas or the etching product and exhaust ability suitable for the etching process, such as an oil rotary pump, a dry pump, and a turbo molecule pump, can be used.

An end of the exhaust port 8 is connected to the vacuum chamber 1 and the other end thereof is connected to the vacuum pump 7, respectively. The exhaust port 8 is disposed below the metal mask 4 so as to obtain exhaust conductance sufficient for the etching process (cleaning process). The exhaust port 8 may be the mechanism which is capable of varying conductance. When the exhaust port 8 is arranged in the vicinity of the center below of the metal mask 4, the etching gas guided between the magnet plate 5 and the metal mask 4 flows well below the metal mask 4 through the opening of the metal mask 4. Accordingly, the re-deposition of the etching product on the metal mask 4 or the lowering of the etching speed can be suppressed, thereby cleaning the metal mask 4 well.

The mask cleaning apparatus may include a pressure adjusting mechanism for adjusting an internal pressure of the vacuum chamber 1 during the etching process. The pressure is preferably in the range of 5 Pa to 100 Pa (more preferably, 10 Pa to 50 Pa). In this case, since the etching can be carried out in an isotropic manner, the organic materials attached to the top surface and the bottom surface of the metal mask 4 and the magnet plate 5, the inside of the hole, and the like can be removed satisfactorily. When the pressure is too low or too high, the etching rate may be decreased or the high-frequency plasma source 2 can be unstable.

Method of Cleaning Metal Mask and Magnet Plate

Next, a method of cleaning the metal mask and the magnet plate by the use of the above-mentioned cleaning apparatus will be described in detail.

(1) First, the metal mask 4 and the magnet plate 5 are placed in the vacuum chamber 1 by the use of the support member 6 with a predetermined gap therebetween.

At this time, the top surfaces and the bottom surfaces of the metal mask 4 and the magnet plate 5 are exposed. That is, the bottom surface of the metal mask 4 to which the organic material or the like can be easily attached is exposed without up/down inverting the metal mask 4 for cleaning the metal mask 4 as in the related art. Therefore, a mechanism or a space for inverting the metal mask can be omitted from the cleaning apparatus, thereby realizing structural simplification and decrease in size of the cleaning apparatus.

(2) Next, etching gas is generated in another chamber disposed outside the vacuum chamber 1 by the use of the high-frequency plasma source 2. The etching gas is mainly in the plasma state.

(3) Next, the generated etching gas is guided into the vacuum chamber 1 through the guide port 3 and the shower head 9.

Since the guided etching gas is changed from the plasma state to the radical state for the above-mentioned reason and is decreased in energy, the damage on the metal mask 4 can be reduced when the metal mask 4 is cleaned by the etching gas.

The guided etching gas is diffused to the top surface side of the magnet plate 5, the space between the magnet plate 5 and the metal mask 4, and the bottom surface side of the metal mask 4, and the etching gas comes in contact with the top and bottom surfaces of the magnet plate 5 and the top and bottom surfaces of the metal mask 4. Accordingly, the organic materials and the like attached to the magnet plate 5 and the metal mask 4 are allowed to chemically react with the etching gas and are removed well, thereby satisfactorily cleaning the metal mask 4 and the magnet plate 5.

The diffused etching gas is sucked by the vacuum pump 7 and is discharged to the outside of the vacuum chamber 1 through the exhaust port 8. At this time, since the materials removed through the chemical reaction are discharged through the exhaust port 8 well, it is possible to prevent the materials from being attached again to the metal mask 4 and the magnet plate 5.

Apparatus for Manufacturing Organic EL Display Device

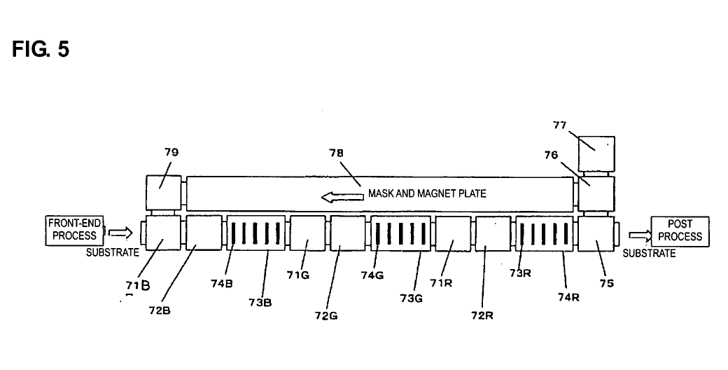

Hereinafter, an apparatus of manufacturing an organic EL display device according to an embodiment of the present invention will be described with reference to FIG. 5.

The manufacturing apparatus shown in FIG. 5 roughly includes alignment units 72R, 72G, and 72B (R denotes forming a red organic layer, G denotes forming a green organic layer, and B denotes forming a blue organic layer, which are true for the following description) for aligning the metal mask 4 with the display substrate 11, film forming apparatuses 73R, 73G, and 73B which have an evaporation source with the carried materials and which serves to form a film on the display substrate 11, a decoupling unit 75 for separating the metal mask 4 from the display substrate 11 and decoupling the integration of both after forming a film on the display substrate 11, a cleaning apparatus 77 described above, and a carrying unit not shown for carrying the metal mask 4 between the units without up/down inverting the metal mask 4. The display substrate 11 includes a glass substrate and lower electrodes corresponding to respective pixels.

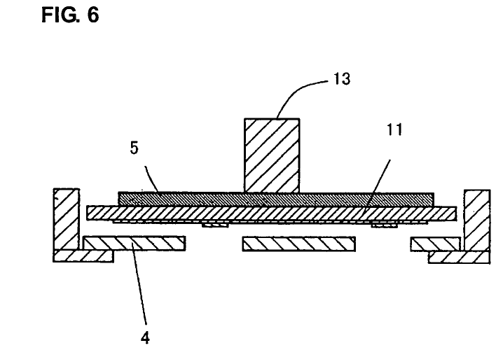

As shown in FIG. 6, the alignment units 72R, 72G, and 72B includes a CCD camera for performing the alignment of the metal mask 4 with the display substrate 11, a magnet plate 5 for adsorbing the top surface side of the metal mask 4, a support rod 13 connected to the top surface of the magnet plate 5, and a lift not shown connected to the top end of the support rod 13. When the alignment of the metal mask 4 with the display substrate 11 is performed by the use of the alignment units, first, the metal mask 4 is aligned with the display substrate 11 by the use of a well-known method using the CCD camera. Next, the magnet plate 5 is lowered with the support rod 13 to come in contact with the display substrate 11 and then the magnet plate 5 and the metal mask 4 are fixed with a magnetic force with the display substrate 11 therebetween. As described above, when the integration of the magnet plate 5 and the metal mask 4 are decoupled from each other, an intermediate plate may be interposed between the magnet plate 5 and the metal mask 4 so as to prevent the deformation of the metal mask 4 due to an external force applied to the metal mask 4.

The film forming apparatuses 73R, 73G, and 73B disposed adjacent to the alignment units 72R, 72G, and 72B, respectively, have the evaporation sources 74R, 74G, and 74B on which a variety of organic materials are mounted. The organic materials mounted on the evaporation sources 74R, 74G, and 74B can include, for example, aluminum complex, a kind of anthracene, rare earth complex, iridium complex, and the like for forming a light emitting layer. The organic materials can include, for example, aryl amines, phthalocyanines, and the like for forming a hole injecting layer. The organic materials can include, for example, aryl amines and the like for forming a hole transporting layer. The organic materials can include, for example, aluminum compound, oxadiazol, triazol, and the like.

The film forming apparatuses 73R, 73G, and 73B deposit the organic material on the display substrate 11 aligned with the metal mask 4 by the alignment units 72R, 72G, and 72B, thereby forming an organic light emitting layer.

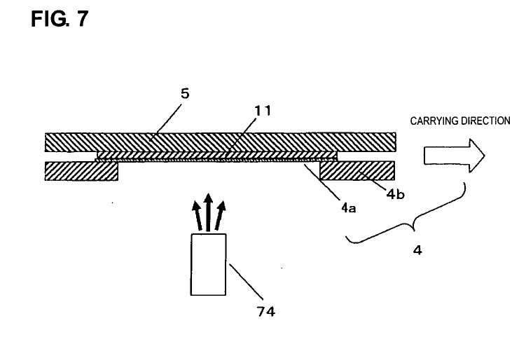

As shown in FIG. 7, in the interior of the film forming apparatus 73, the metal mask 4, the display substrate 11, and the magnet plate 5 are integrally disposed above the evaporation source 74. When the evaporation source 74 is heated to more than vaporized temperature of the organic material, the organic material is vaporized and deposited on the display substrate exposed from the openings of the metal mask 4, thereby forming the organic light emitting layer on the display substrate 11. In general, since the organic light emitting layer includes a variety of layers such as an electron injecting layer, an electron transporting layer, a light emitting layer, a hole transporting layer, and a hole injecting layer, a plurality of evaporation sources corresponding to each of the layers in the organic light emitting layer is disposed with a predetermined gap in the film forming apparatuses 73R, 73G, and 73B. It is preferable that the evaporation sources have a long shape so as to prevent non-uniformity in thickness of the layers. It is also preferable that the vapor deposition is performed while moving the display substrate 11 so as to prevent non-uniformity in thickness of the layers.

Buffer chambers 71R, 71G, and 71B are disposed in the vicinity of the film forming apparatuses 73R, 73G, and 73B or the alignment units 72R, 72G, and 72B. The buffer chambers 71R, 71G, and 71B are spaces for temporarily keeping the display substrate 11 so as to adjust the time to carry the display substrate 11 downstream and are disposed at the upstream side from the alignment units in the carrying direction of the display substrate 11.

The buffer chambers 71R, 71G, and 71B, the alignment units 72R, 72G, and 72B, and the film forming apparatuses 73R, 73G, and 73B are arranged from the upstream side to the downstream side in the carrying direction of the display substrate 11 in the order of the buffer chamber 71B, the alignment unit 72B, the film forming apparatus 73B, the buffer chamber 71G, the alignment unit 72G, the film forming apparatus 73G, the buffer chamber 71R, the alignment unit 72R, and the film forming apparatus 73R.

The decoupling unit 75 is disposed at the downstream side from the film forming apparatus 73R in the carrying direction. The decoupling unit 75 serves to decouple the metal mask 4, the display substrate 11, and the magnet plate 5 integrally coupled to each other with the magnetic force of the magnet plate 5 and decouples the metal mask 4 and the magnet plate 5 by applying an external force to them by the use of an hydraulic cylinder or a pusher pin driven with a motor and the like.

The decoupling unit 75 is connected to the cleaning apparatus 77 through a mask transfer unit 76. The cleaning apparatus 77 has basically the same structure as the above-described cleaning apparatus.

The carrying means for carrying the metal mask 4, the magnet plate 5, and the display substrate 11 can include a roller carrier or a robot. The carrying means does not necessarily include a mechanism for up/down inverting the metal mask 4 or the magnet plate 5. Accordingly, the structure of the carrying means can be simplified and a large space for up/down inverting the metal mask 4 or the magnet plate 5 is not necessary. Therefore, it is possible to contribute to decrease in size of the apparatus of manufacturing an organic EL display device.

Method of Manufacturing Organic EL Display Device

Next, a method of manufacturing an organic EL display device by the use of the manufacturing apparatus shown in FIG. 5 will be described in detail.

(1) First, in a front-end process the display substrate 11 is carried into a buffer chamber 71B and the metal mask 4 and the magnet plate 5 are carried into the buffer chamber 71B from a mask stocker 79, respectively.

(2) Next, the magnet plate 5, the metal mask 4, and the display substrate 11 are carried to the alignment unit 72B from the buffer chamber 71B at a predetermined timing.

(3) The metal mask is aligned with the display substrate by the alignment unit and then the magnet plate, the display substrate, and the metal mask are integrally fixed to each other by the use of the magnet plate (hereinafter, the magnet plate, the display substrate, and the metal mask integrally fixed to each other are referred to as a set substrate).

(4) Subsequently, the set substrate is carried into the film forming apparatus 73B by the use of the carrying unit such as a roller carrier and the organic material corresponding to blue is vaporized from the evaporation source 74B, thereby forming a blue organic light emitting layer on the display substrate 11 exposed from the openings of the metal mask 4.

(5) Subsequently, the set substrate is carried to the buffer chamber 71G and then is carried to the alignment unit 72G at a predetermined timing.

(6) Then, by repeating the process steps (3) to (5) using the alignment unit 72G, the film forming apparatus 73G, the alignment unit 72R, and the film forming apparatus 73R, a green organic light emitting layer and a red organic light emitting layer are formed on the display substrate 11.

(7) Next, the set substrate is carried to the decoupling unit 75 and the set substrate is decoupled into the individual members (the display substrate 11, the metal mask 4, and the magnet plate 5) by the decoupling unit 75.

(8) After the set substrate is decoupled, the display substrate 11 is sent to a post-process and the lower electrodes or a protection film is formed on the organic light emitting layer. On the other hand, the metal mask 4 and the magnet plate 5 are not up/down inverted and are carried to the cleaning apparatus 77 through the mask transfer unit 76 by the use of the carrying unit such as a robot. The metal mask 4 and the magnet plate 5 are cleaned in the cleaning apparatus 77. As described above, since the cleaning apparatus 77 can clean the bottom surface of the metal mask to which the organic materials are mainly attached without inverting the metal mask 4, a mechanism and a space for inverting the metal mask 4 are not required, thereby simplifying the structure of the apparatus and decreasing the size thereof.

(9) The metal mask 4 and the magnet plate 4 having been subjected to the cleaning process are carried to the mask stocker 79 through the mask carrying chamber by the use of the carrying unit such as a roller carrier.

(10) The metal mask 4 and the magnet plate 5 carried to the mask stocker 79 are carried to the buffer chamber 71B. At this time, a display substrate 11 is carried to the buffer chamber 71B from a front-end process.

(11) While repeating the process steps (2) to (10), the metal mask 4 and the magnet plate 5 are reused.

The buffer chambers, the alignment units, the film forming apparatus, the decoupling unit, the mask transfer unit, the cleaning apparatus, the mask carrying chamber, and the mask stocker perform processes in a decompressed atmosphere obtained by exhausting the respective chambers with a vacuum pump not shown. Accordingly, since the metal mask 4 and the magnet plate 5 are kept in a vacuum state in the course of a series of processes (including the processes of carrying the metal mask, aligning the metal mask, and the like) from the process of cleaning the metal mask to the process of forming a film on the display substrate and from the process of forming a film on the display substrate to the process of cleaning the metal mask, it is possible to prevent attachment of particles or dust to the metal mask 4 or the magnet plate 5 before or after cleaning the metal mask.

The metal mask 4, the magnet plate 5, and the display substrate 11 may be processed in a unit of plural sets. In this case, it is possible to efficiently form the organic light emitting layers with a short tact time.

The cleaning of the metal mask 4 and the magnet plate 5 may be performed every time and may be performed every N times (where N is a natural number greater than 1). When the cleaning of the metal mask 4 and the magnet plate 5 is performed every N times, a process of reusing the metal mask 4 and the magnet plate 5 without cleaning them is performed. In such a process, the metal mask 4 separated by the decoupling unit 75 is not carried to the cleaning apparatus 77, but is carried to the mask stocker 79 through the mask transfer unit 76 and the mask carrying chamber 78.

The present invention is not limited to the above-mentioned embodiment, but may be diversely modified and improved within the scope of the invention.

For example, in the above-mentioned embodiment, it has been described that the mask cleaning apparatus is used in the apparatus and method of manufacturing an organic EL display device, but the present invention may be applied to an apparatus or method of manufacturing an inorganic EL display device.

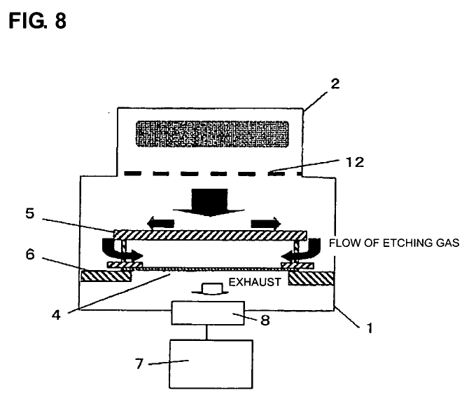

In the mask cleaning apparatus according to the above-mentioned embodiment, the high-frequency plasma source 2 is disposed outside the vacuum chamber 1, but instead, the high-frequency plasma source 2 may be disposed inside the vacuum chamber 1. In this case, for example, as shown in FIG. 8, the installation place of the high-frequency plasma source 2 is set different from the installation place of the metal mask 4. It is preferable that a shielding plate 12 having a plurality of holes is disposed in the boundary between the installation place of the high-frequency plasma source 2 and the installation place of the metal mask 4. It is preferable that the shielding plate 12 may be made of aluminum or SUS. It is preferable that the high-frequency plasma source 2 may employ a down-flow plasma source such as an ICP type, as SWP type, and an NLD type used conventionally.

In the above-mentioned embodiment, the mask cleaning apparatus may further comprise a heating means for heating the metal mask 4 and the magnet plate 5. An example of the heating means can include an infrared ray heater or a hot plate, and the like. The heating unit preferably heats the metal mask 4 and the magnet plate 5 in the course of cleaning the metal mask 4 and the magnet plate 5. In this case, the etching rate is enhanced, thereby performing the cleaning process for a short time. The metal mask 4 and the magnet plate 5 are preferably heated to a temperature of 10° C. to 70° C. When the temperature is higher than 70° C., the deformation or the deterioration in dimensional precision of the metal mask can be caused. From an experimental result by the inventor, it could be seen that the etching rate of a degree of 300 nm/min at 50° C. is obtained with respect to the metal mask 4.

The heating means may be disposed outside the mask cleaning apparatus, not inside the mask cleaning apparatus. In this case, in the apparatus of manufacturing an organic EL display device, a heating means is disposed in the decoupling unit 75 or the mask transfer unit 76 and thus the metal mask 4 or the magnet plate 5 is heated in advance before cleaning the metal mask 4.

When the heating means is disposed inside or outside the mask cleaning apparatus, it is preferable that a cooling unit for cooling the metal mask 4 and the magnet plate 5 after cleaning the metal mask is disposed outside the mask cleaning apparatus (in the mask stocker 79 or the buffer chamber 71B in the above-mentioned apparatus for manufacturing an organic EL display device). This is because the dimension of the metal mask 4 can be varied by thermal expansion and positional deviation from the substrate to be aligned can easily occur in the state that the metal mask 4 is heated. A cooling plate, a cooling roller, inert gas such as N₂, Ar, and He which contact with the metal mask 4 and the magnet plate 5 can be considered as the cooling means.

### EXPERIMENTAL EXAMPLE 1

In Experimental example 1, the process of cleaning the metal mask was performed by the use of the cleaning apparatus shown in FIG. 1. A 600 mm×350 mm metal mask and a magnet plate in which a neodymium magnet is disposed in a 600 mm×350 mm×10 mm SUS vessel were placed with a gap of 20 mm in a 650 mm×650 mm×250 mm vacuum chamber made of aluminum. CF₄ of 75 sccm, O₂ of 425 sccm, and N₂ of 50 sccm were introduced as etching gas into a quartz tube and microwaves were introduced thereto through a waveguide from a microwave oscillator with 2.45 GHz and 1 kW, thereby exciting the etching gas into plasma. The etching gas was guided into the vacuum chamber through a port connected to the vacuum chamber, thereby performing a cleaning process. The pressure of the vacuum chamber was 35 Pa at the time of performing the cleaning process. A sample in which a well-known organic film such as phthalocyanine film, an Alq₃ film, and an NPB film is formed on the bottom surface of a metal mask was prepared and subjected to an etching process. Any material attached to the surface of the metal mask could be satisfactorily etched and removed at an etching rate of 25 nm/min with CF₄ of 50 to 100 sccm and O₂ of 400 to 450 sccm.

As a result of the same test in a state that the metal mask and the magnet plate are heated at 50° C., an etching rate of 300 nm/min was obtained.

As a result of the same test in a state that the top surface of the magnet plate is covered with a sheet made of polytetrafluoroethylene, an etching rate of about 1.7 times (42.5 nm/min) was obtained.

What is claimed is:

1. A method of forming a vapor-deposited film comprising the steps of:
aligning a mask having a plurality of openings with a substrate;
forming a film on the substrate through the openings of the mask by the use of a vapor deposition method; and
carrying and cleaning the mask in a state that the top surface and the bottom surface of the mask used for forming the film are not inverted to maintain the vertical relation of the mask.

2. The method according to claim 1, wherein after aligning the mask with the substrate, the mask is fixed to the substrate by the use of a magnetic force of a magnet plate.

3. The method according to claim 2, wherein the magnet plate is cleaned along with the mask.

4. The method according to claim 1, further comprising a step of heating the mask before or during cleaning the mask.

5. The method according to claim 4, further comprising a step of cooling the mask after heating the mask.

6. The method according to claim 1, wherein the aligning of the mask with the substrate, the forming of a film on the substrate, the carrying of the mask, and the cleaning of the mask are performed under vacuum.

7. The method according to claim 1, wherein the forming of a film on the substrate and the cleaning of the mask are performed in different chambers.

8. A method of manufacturing an EL display device comprising the steps of:
aligning a mask having a plurality of openings with a first display substrate;
depositing a first organic material on the first display substrate through the openings of the mask and forming a first organic light emitting layer on the first display substrate;
cleaning the mask in a state that the top surface and the bottom surface of the mask used for forming the first organic light emitting layer are not inverted to maintain the vertical relation of the mask;
aligning the cleaned mask with a second display substrate; and
depositing a second organic material on the second display substrate through the openings of the mask and forming a second organic light emitting layer on the second display substrate.

9. The method according to claim 8, wherein after the aligning of the mask with the first or second display substrates, the mask is fixed to the one of the first and second display substrates by the use of a magnetic force of a magnet plate.

10. The method according to claim 8, wherein the magnet plate is cleaned along with the mask.

11. The method according to claim 8, further comprising a step of heating the mask before or during cleaning the mask.

12. The method according to claim 11, further comprising a step of cooling the mask after heating the mask.

13. The method according to claim 8, wherein the carrying of the mask, the cleaning of the mask, the forming of the first organic light emitting layer and the second organic light emitting layer, and the aligning of the mask with the first and second display substrates are performed in vacuum.

14. The method according to claim 8, wherein the forming of the first organic light emitting layer or the second organic light emitting layer and the cleaning of the mask are performed in different chambers.
